(19) United States
(12) Patent Application Publication
(10) Pub. No.: US 2019/0244827 A1
(43) Pub. Date: Aug. 8, 2019

(54) APPARATUS AND METHOD FOR ANISOTROPIC DRIE ETCHING WITH FLUORINE GAS MIXTURE

(71) Applicant: FRAUNHOFER GESELLSCHAFT ZUR FOERDERUNG DER ANGEWANDTEN FORSCHUNG E.V., Munich (DE)

(72) Inventor: Robert WIELAND, Munchen (DE)

(21) Appl. No.: 16/385,345

(22) Filed: Apr. 16, 2019

Related U.S. Application Data
(63) Continuation of application No. PCT/EP2017/076265, filed on Oct. 16, 2017.

(30) Foreign Application Priority Data
Oct. 17, 2016 (DE) 10 2016 220 248.

(51) Int. Cl. H01L 21/3065; H01J 37/32; H01L 21/67

(52) U.S. Cl. CPC H01L 21/30655; H01J 2237/3341; H01L 21/67069; H01J 37/3244

(57) ABSTRACT

An etching method for anisotropically structuring a substrate by means of deep reactive-ion etching (DRIE) includes several alternating successive etching steps and passivation steps. According to the invention, a fluorine gas mixture having a proportion of more than 25% up to and including 40% of fluorine, a proportion of 1% to 50% of nitrogen and a proportion of 30% up to and including 60% of a noble gas is used for etching. In addition, the invention concerns the use of such a fluorine gas mixture as well as a corresponding apparatus for structuring a substrate by means of the inventive fluorine gas mixture.

### CROSS-REFERENCES TO RELATED APPLICATION

This application is a continuation of copending International Application No. PCT/EP2017/076265, filed Oct. 16, 2017, which is incorporated herein by reference in its entirety, and additionally claims priority from German Application No. DE 10 2016 220 248.0, filed Oct. 17, 2016, which is incorporated herein by reference in its entirety.

### BACKGROUND OF THE INVENTION

The invention concerns a method for deep reactive-ion etching (DRIE) using a fluorine gas mixture having the features of claim 1, the use of such a fluorine gas mixture for deep reactive-ion etching having the features of claim 10, and an apparatus having a reactor for deep reactive-ion etching using the inventive fluorine gas mixture having the features of claim 12.

In order to manufacture semiconductor elements and MEMS (Micro Electromechanical Structures) systems, substrates are structured. For this, different etching processes may be used. Wet-chemical etching methods and dry-etching methods are known, the latter being divided into chemical and physical processes.

Chemical dry-etching (CDE) processes involve a chemical reaction between the neutral particles/molecules (usually radicals) and the surface of the substrate, which leads to the substrate being structured. The radicals are generated in a plasma, which is why the chemical dry-etching process is commonly referred to as plasma etching method. The chemical dry-etching processes usually show a very isotropic etching behavior.

The physical dry-etching methods, on the other hand, show a rather anisotropic etching pattern. Here, the surface of the substrate is etched by the bombardment with ions, electrons or photons. The processes involved in structuring the substrate are similar to those involved in sputtering. Physical dry-etching methods, however, usually have a relatively low etching rate which further comprises only a low material selectivity. The associated etching of the mask results in rounded edges. In addition, high energies are needed for the etching so that the ions penetrate a material to a greater depth. Thus, etching is not only carried out at the surface, but deeper layers are also damaged. Another disadvantage are parasitic depositions (redepositions) of the etched particles on the substrate and the mask, or the mask edges.

A mixed form of the two dry-etching methods, which combines the advantages of the chemical and the physical dry-etching, is the physical-chemical dry-etching method (physical-chemical dry-etching), commonly referred to as plasma-assisted etching. The educts are usually activated or radicalized by a plasma and then guided onto the substrate by ion acceleration. Well-known representatives of the physical-chemical dry-etching methods are reactive-ion etching (RIE) and deep reactive-ion etching (DRIE). Deep reactive-ion etching (DRIE) is also known as the Bosch process.

In all of the above-mentioned etching methods, special gases or gas mixtures are used as the etching gas. The respective etching gases are specific to the respective etching method. Particularly in the case of gas mixtures, deviations of as little as 1% of a respective gas component may lead to the selected etching method no longer being executable.

For example, sulfur hexafluoride SF₆ is used as the etching gas for the deep reactive-ion etching since SF₆ allows for a very good and reproducible process control. Sulfur hexafluoride SF₆ is also easy to handle and relatively harmless.

However, sulfur hexafluoride SF₆ is an extremely harmful gas for the environment, having a GWP value of >22800 (GWP=Global Warming Potential), and contributes greatly to global warming (“climate killer”). Furthermore, in continuous operation, etching equipment accumulates large quantities of partially reacted sulfur compounds in the vacuum pump lines of the reactors. This is not desirable in 24-hour operation and causes comparatively high maintenance costs.

### SUMMARY

According to an embodiment, an etching method may have the steps of: anisotropically structuring a silicon substrate by means of deep reactive-ion etching (DRIE) with several alternating successive etching steps and passivation steps, wherein a fluorine gas mixture is used for etching, having a proportion of more than 25% up to and including 40% of fluorine, a proportion of 1% to 50% of nitrogen and a proportion of 30% up to and including 60% of a noble gas.

Another embodiment may have the use of a fluorine gas mixture for anisotropically structuring a silicon substrate by means of deep reactive-ion etching (DRIE) with several alternating successive etching steps and passivation steps, wherein the fluorine gas mixture is used for etching and has a proportion of more than 25% up to and including 40% of fluorine, a proportion of 1% up to 50% of nitrogen and a proportion of 30% up to and including 60% of a noble gas from the group comprising argon, neon, krypton, helium, radon and xenon.

The inventive etching method comprises anisotropically structuring a substrate by means of deep reactive-ion etching (DRIE) with several alternating successive etching steps and passivation steps. In accordance with the invention, a fluorine gas mixture having a proportion of more than 25% up to and including 40% of fluorine (25%<F₂<=40%), a proportion of 1% to 50% of nitrogen (1%<=N₂<=50%) and a proportion of 30% up to and including 60% of a noble gas (30%<=noble gas<=60%) is used for etching. This special composition of the inventive fluorine gas mixture is very well suited to replace the previously used SF₆. The invention is based on the fact that, according to previous knowledge, F₂ fluorine gas mixtures have a strongly isotropic etching behavior, i.e. in contrast to fluorine-containing molecules (e.g. CF₄, CHF₃, C₄F₈, etc.), F₂ fluorine gas mixtures are not suitable for realizing fine structures in the nanometer range, e.g. semiconductor components, since pure reactive-ion etching with correspondingly high selectivities to the side-wall (=very smooth side surface of the generated structures) is used for this purpose. Therefore, F₂ fluorine gas mixtures are only used for cleaning CVD systems, wherein the CVD systems are flooded with the F₂ fluorine gas mixture and an isotropic etching behavior is desired. Almost all conventional plasma systems used for fine structuring of semi-conductor or MEMS components using photoresist masks need a corresponding selectivity to the mask as well as a continuous sidewall passivation in order to avoid the undesired “undercut” (=underetching the layer to be etched). However, this is usually only possible by using polymerizing gases such as CHF₃. In this respect, F₂-gas mixtures cannot be used for this purpose or can only be used to a very limited extent, since F₂ gas mixtures with their high radical density would only etch isotropically without additional polymerization gas, i.e. produce undercut, and therefore cannot be considered for anisotropic etching. However, with the gas composition according to the invention, contrary to previous assumptions, it has been possible to use F₂ fluorine gas mixtures for anisotropically structuring substrates.

As already mentioned at the beginning, in DRIE etching methods, deviations of the gas compositions even in a range of only 1% may lead to a considerable change in the etching rate and the feasibility of the method. While conducting an experiment, it was surprising to learn that a fluorine gas mixture having a proportion of 35% up to and including 40% of fluorine, a proportion of 1% to 50% of nitrogen and a proportion of 30% up to and including 59% of a noble gas has produced significantly better results in terms of etching rate and process control than the theoretical expectations of this composition.

It is conceivable that the fluorine gas mixture contains a noble gas from the group of argon, neon, krypton, helium, radon and xenon.

According to an embodiment, the fluorine gas mixture may comprise argon as the only noble gas component. It was shown that the use of argon in combination with F₂ and N₂ has yielded particularly good results in etching by means of the inventive method.

According to another embodiment, the step of the passivation includes applying a passivation layer onto the substrate by using C₄F₆ as the process gas. So far, the polymerization gas C₄F₈ has been used for passivation in known DRIE processes. However, this polymerization gas C₄F₈ is very harmful to the environment, i.e. it has a GWP index of 8700 (Global Warming Potential). However, the polymerization gas C₄F₆ is much more environmentally friendly, i.e. this process gas has a GWP index of 1. Thus, the inventive substitution of C₄F₈ by C₄F₆ further contributes to solving the underlying problem of the invention, namely to make known DRIE processes much more environmentally friendly.

According to embodiments of the invention, among other things, the method includes generating reactive ions in a high-frequency direct plasma. In contrast to so-called remote-plasma, in a direct plasma, the plasma is directly generated in the etching chamber. High-frequency direct plasmas are understood to be plasmas that are generated with an excitation frequency of 3 MHz to 300 GHz.

Here, it is conceivable that the method includes generating reactive ions in an inductively or capacitively coupled high-frequency direct plasma with an excitation frequency in the shortwave frequency band in a frequency range of 3 MHz to 30 MHz. An advantageous high-frequency range spans from 10 MHz to 15 MHz. For example, a selected frequency would be 13.56 MHz.

According to further embodiments of the invention, the method includes generating reactive ions in a high-frequency plasma with an excitation frequency in the microwave frequency band in a frequency range of 0.3 GHz to 3 GHz. An advantageous high-frequency range spans from 2 GHz to 3 GHz. For example, a selected frequency would be 2.45 GHz. In known DRIE processes using SF₆ as etching gas, microwave excitation is not used since microwave excitation, e.g. at 2.5 GHz, is unsuitable for heavy gases such as SF₆, since the high-frequency power needed in order to dissociate SF₆ into F radicals may be coupled in only in an extremely complex and insufficiently high manner. In combination with the present invention, which uses the claimed F₂ fluorine gas mixture as etching gas, the use of microwave excitation is synergistically very interesting. Fluorine gas mixtures dissociate into fluorine radicals already at a power density which is three times lower in comparison and therefore permit a high fluorine radical density even with microwave excitation. Microwave plasmas therefore generate very high radical densities with comparatively low energy input, which leads to a considerably higher F radical density, particularly when using fluorine gas mixtures.

In order to achieve a sufficiently good etching homogeneity across a corresponding silicon substrate (diameter 200-300 mm) by using microwave excitation, a further embodiment is the use of several, individually controlled microwave coupling sources that are regularly arranged in a planar manner and are able to optimize the silicon homogeneity or mask homogeneity of the ablation rate by means of maximum frequency power control.

According to further embodiments, the inventive method includes generating reactive fluorine ions and fluorine radicals, wherein more reactive fluorine ions are generated in a first time period than fluorine radicals, and wherein more fluorine radicals are generated in a subsequent second time period than reactive fluorine ions. The reactive fluorine ions are needed to break open the passivation layer, or polymerization layer. On the other hand, the radicals etch with a high selectivity the substrate to be structured. Therefore, according to the invention, reactive fluorine ions are first generated at the beginning of an etching step (e.g. for half a second) and then directed onto the substrate in order to break through the passivation layer applied in the previous passivation step. Subsequently, fluorine radicals are generated and guided onto the exposed substrate in order to etch, or structure, the substrate. For example, the generation of radicals and reactive ions in a specified time window may be realized by means of a controller connected to the plasma source, configured to control the plasma source accordingly so that the plasma source produces at different times different distributions of proportions of fluorine radicals and fluorine ions within the plasma.

A further aspect of the invention is the use of a fluorine gas mixture for anisotropically structuring a substrate by means of deep reactive-ion etching (DRIE) with several alternating successive etching steps and passivation steps, wherein the fluorine gas mixture has a proportion of more than 25% up to and including 40% of fluorine (25%<F₂<=40%), a proportion of 1% to 50% nitrogen (1%<=N₂<=50%) and a proportion of 30% up to and including 60% of a noble gas (30%<=noble gas<=60%).

A further aspect of the invention concerns an apparatus with a reactor for anisotropically structuring a substrate by means of deep reactive-ion etching (DRIE) with several alternating successive etching steps and passivation steps, and a gas inlet for feeding an etching gas into the reactor, wherein a fluorine gas mixture is used as the etching gas, having a proportion of more than 25% up to and including 40% of fluorine (25%<F₂<=40%), a proportion of 1% to 50% of nitrogen (1%<=N₂<=50%) and a proportion of 30% up to and including 60% of a noble gas (30%<=noble gas<=60%).

### BRIEF DESCRIPTION OF THE DRAWINGS

Embodiments of the present invention will be detailed subsequently referring to the appended drawings, in which:

FIG. 1 shows a schematic sectional view of a substrate structured by means of the inventive method,

FIG. 2 shows a conventional plasma system for deep reactive-ion etching using SF₆ as a process gas according to the conventional technology, and

FIG. 3 shows an inventive plasma system for deep reactive-ion etching using the inventive fluorine gas mixture as the process gas.

### DETAILED DESCRIPTION OF THE INVENTION

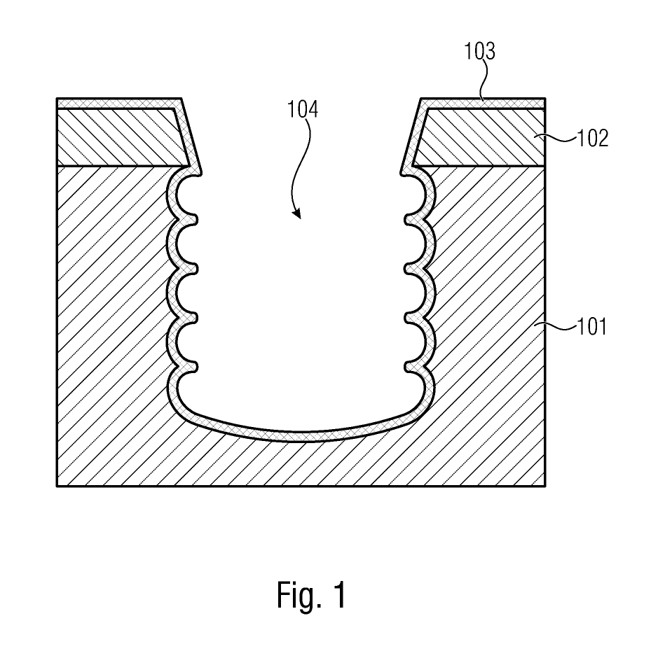

FIG. 1 schematically shows the etching pattern of a substrate 101 structured using an inventive DRIE process. The DRIE process is commonly referred to as the Bosch process.

The peculiarity of the Bosch process is that it regularly changes between isotropic Si etching and isotropic polymerization and needs comparatively little anisotropy per Si etching step, primarily at the beginning of each Si etching step. Although the individual etching steps may be isotropic, the structure 104 etched into the substrate 101 exhibits a high anisotropy due to the alternating etching and polymerization steps.

The silicon substrate 101 exemplarily shown in FIG. 1 also has a passivation layer (e.g. oxide) 102. The repeating passivation step mentioned above also leads to the deposition of a further passivation layer or polymer layer 103 on the substrate 101. This polymer layer 103 also results in a bottom passivation and sidewall passivation within the cavity 104.

The Bosch process involves an alternating and recurring combination of reactive-ion etching and polymer deposition for generating deep trenches, cavities or TSVs (Through Silicon Vias) 104 in silicon substrates 101. To date, in Bosch processes according to the conventional technology, the gas C₄F₈ is used for polymer deposition and the etching gas SF₆ is used for the actual Si etching.

A conventional Bosch process essentially consists of three process steps:
a) isotropic chemical etching by means of F radicals (formed from SF₆)
b) passivation of the surface by means of C₄F₈ gas, isotropic, no bias RF
c) removing the bottom passivation by means of accelerated ions (physical etching)

The etching chambers used in the conventional technology all use a so-called inductively coupled plasma excitation at a frequency of 13.56 MHz, paired with a simultaneously applied additional plasma source at a frequency of 13.56 MHz or 400 kHz, which generates a so-called DC bias or acceleration voltage via the cathode.

The plasma that is inductively coupled at the top of the reactor produces a relatively high density of undirected fluorine ions and fluorine radicals, etching the silicon 90% isotropically, predominantly due to the high-radical density produced. The superimposed second plasma source accelerates SFₓ ions perpendicularly towards the wafer surface and therefore generates the anisotropic etching proportion, which is controlled independently of the inductive source.

The anisotropic etching part is only needed to break through the previously deposited thin Teflon-like polymer layer 102 at the bottom of the trench 104 to be created (the polymer is retained on the sidewalls of the trench 104 to protect against undercutting, thus allowing the next isotropic Si etching by fluorine radicals).

Polymerization is achieved by “depositing” a thin, PTFE-like layer by igniting a C₄F₈ plasma, only by applying the inductively coupled 13.56 MHz power, without bias RF.

The etching gas SF₆ used in conventional Bosch processes is a gas that is extremely harmful to the environment, having a GWP value of >22800 (GWP=Global Warming Potential), and contributes greatly to global warming (“climate killer”). In addition, large quantities of partially reacted sulfur compounds accumulate in the vacuum pump lines of the reactors in continuous operation of above-mentioned etching equipment. This is not desirable in a 24-hour operation and results in comparatively high maintenance costs.

Therefore, the invention provides, among other things, to replace the previously used etching gas SF₆ in the Bosch process with fluorine gas mixtures in order to be able to produce lithographically specified deep structures 104 in a substrate (e.g. bulk silicon) 101, with aspect ratios far in excess of the factor 20:1 (aspect ratio=depth to trench width).

According to the invention, the fluorine gas mixture includes a proportion of more than 25% up to and including 40% of fluorine (25%<F₂<=40%), a proportion of 1% to 50% of nitrogen (1%<=N_{2<}=50%) and a proportion of 30% up to and including 60% of a noble gas (30%<=noble gas<=60%). Argon is advantageously used as the noble gas.

Significantly better results may be achieved with a fluorine gas mixture containing a proportion of 35% up to and including 40% of fluorine, a proportion of 1% up to 50% of nitrogen and a proportion of 30% up to and including 59% of a noble gas.

The fluorine gas mixtures may also consist of F₂/noble gases (He, Ar, neon, krypton, xenon)/N₂ in concentrations within the claimed limits in order to be able to optimize needed selectivities and anisotropic etching proportions.

Up to this point, fluorine gas mixtures have been known to have a very high isotropy, i.e. fluorine gas mixtures etch in a largely undirected manner. Therefore, fluorine gas mixtures are very suitable as cleaning gas for the cleaning of CVD chambers, for example. The fluorine gas mixture floods the CVD chamber and is distributed over a large area in the chamber, e.g., to isotropically etch and remove residues from the chamber walls. This large isotropy is therefore desirable for cleaning. According to general expert knowledge, however, fluorine gas mixtures are not suitable for the directional structuring of substrates due to this large isotropy.

In contrast to CVD cleaning plasmas in which F₂ gas mixtures are used for the full surface removal of glass layers or amorphous silicon layers on the CVD reactor walls, for example, the present invention describes the first use of F₂ gas mixtures for the generation of structures and substrates (e.g. silicon wafers) with the declared aim of being able to replace the SF₆ gas, which was previously used exclusively, for environmental reasons and at the same time to be able to increase the service life of the etching chambers and vacuum components, since interfering sulfur depositions cannot occur.

The approach of replacing SF₆ in DRIE etching of photomask-structured silicon with environmentally friendly F₂ gas mixtures also needs a different technical approach in comparison to CVD cleaning processes in which fluorine gas mixtures are guided into the chamber in an undirected manner in order to flood the same. Apart from this, the compositions, or percentage distributions, of the individual gas components of the fluorine gas mixtures used in CVD cleaning processes differ from the composition of the fluorine gas mixture according to the invention. It should be mentioned here that, in the case of fluorine gas mixtures, deviations of even 1% of a single mixed component may result in the desired method no longer being performable.

In DRIE etching, since the needed selectivity to Teflon-like polymer layers as well as a minimal anisotropy when breaking through with the same layer have to be shown in order to be able to perform the actual Si etching, the addition of N₂ and noble gases (e.g. argon as a comparably heavy atom) into the F₂ gas mixture is a new solution approach in order to be able to achieve the needed sputter energy in the repeated opening of the previously polymerized trench bottoms.

The use of F₂ gas mixtures instead of 100% of F₂ is advantageous for security reasons since 100% of F₂ is self-igniting and highly reactive. In addition, 100% of F₂ does not achieve the needed selectivity of silicon to conventional masking layers such as photoresist, Si glasses or silicon nitride, which is another reason why fluorine gas mixtures have not yet been used in reactive-ion etching.

The inventive method may either be realized in a conventional inductively coupled plasma (e.g. at 13.56 MHz) or using a microwave plasma (e.g. at 2.45 GHz).

The use of the inventive fluorine gas mixture in combination with a microwave plasma has many advantages.

For example, microwave plasmas generate very high radical densities at comparably low use of energy, which leads to a considerably higher fluorine radical density compared to plasma excited at a lower frequency, especially when fluorine gas mixtures are used.

Since an additional matching unit (electromechanical high-frequency adjusting unit) is not required when using microwaves for the formation of F₂ radicals, the advantage for an inventive apparatus is that it may be built more reliably than the process chambers currently used with inductively coupled plasma (e.g. at 13.56 MHz).

The polymerization gas C₄F₈ may still be used. However, C₄F₈ used for the passivation and the etching gas SF₆ used for etching in the conventional technology are very harmful to the environment. According to the invention, it is therefore intended to use C₄F₆ or SF₄ as possible alternatives to C₄F₈ and SF₆. C₄F₆ has a GWP index of only 1 (C₄F₆: GWP=1) in comparison to C₄F₈ (C₄F₈: GWP=8700).

Only the latest design microwave sources which are coupled in by ceramic surfaces with ceramic waveguides arranged several times next to each other generate the needed planar and uniformly distributed radical density over the entire wafer surface in order to achieve uniform Si removal.

The more complex approach of combining several individually controllable microwave sources in a matrix-like, regularly distributed arrangement allows the further optimization of the achievable homogeneity of silicon substrates in the diameter range of 200 mm to 300 mm. The individually controllable microwave power adaption per coupling element makes it possible to adapt, over the entire reactor surface in a very exact manner, the ion energy distributed across the etching chamber and the radical density distributed across the etching chamber in order to achieve an etching ablation that is as homogeneous as possible.

A second RF generator at 13.56 MHz or at 400 kHz is only needed to be able to generate an adjustable and finely controllable ion acceleration (sputter etching step) at the polymer opening towards the cathode or wafer surface, respectively. The inventive fluorine gas mixture, which is very easily dissociable, needs a relatively low RF power to produce a fluorine radical density comparable to SF₆ and therefore also a high Si etching rate.

In the inventive method, it is advantageous if fluorine ions are available for breaking open the passivation layer or polymerization layer 103, wherein fluorine radicals are desired for structuring the substrate 101 (after breaking open the passivation layer or polymerization layer 103).

Therefore, according to embodiments of the invention, the inventive method includes generating reactive fluorine ions and fluorine radicals, wherein more reactive fluorine ions are generated in a first time period than fluorine radicals, and wherein more fluorine radicals are generated in a subsequent second time period than reactive fluorine ions.

The reactive fluorine ions are needed to break open the passivation or polymerization layer 103. On the other hand, the fluorine radicals etch with high selectivity the substrate 101 to be structured. Therefore, according to the invention, reactive fluorine ions are first generated at the beginning of an etching step (e.g. for half a second) and then directed onto the substrate 101 in order to break through the passivation layer or polymerization layer 103 applied in the previous passivation step. Subsequently, fluorine radicals are generated and guided onto the exposed substrate 101 in order to etch, or structure, the substrate 101.

For example, the generation of radicals and reactive ions in a certain time window may be realized by means of a controller connected to the plasma source, configured to control the plasma source accordingly so that the plasma source produces at different times different distributions of proportions of fluorine radicals and fluorine ions within the plasma.

For example, the controller may be configured to increase the excitation frequency for generating the plasma depending on the time. At high-frequencies below the microwave frequency range, i.e. at frequencies of approximately 30 MHz to 300 MHz, both radicals and reactive ions are formed in the plasma. At a frequency in the microwave frequency range, i.e. at frequencies of approximately 0.3 GHz to 3 GHz, the ions may no longer follow these high frequencies, and almost only radicals are formed in the plasma.

Thus, the controller may be configured to generate in the first time period the plasma at a first excitation frequency and in a second time period at a second excitation frequency, wherein the first excitation frequency is lower than the second excitation frequency and wherein the first excitation frequency is advantageously below the microwave frequency range, i.e. at about 30 MHz to 300 MHz, and the second excitation frequency is within the microwave frequency range of 0.3 GHz to 3 GHz.

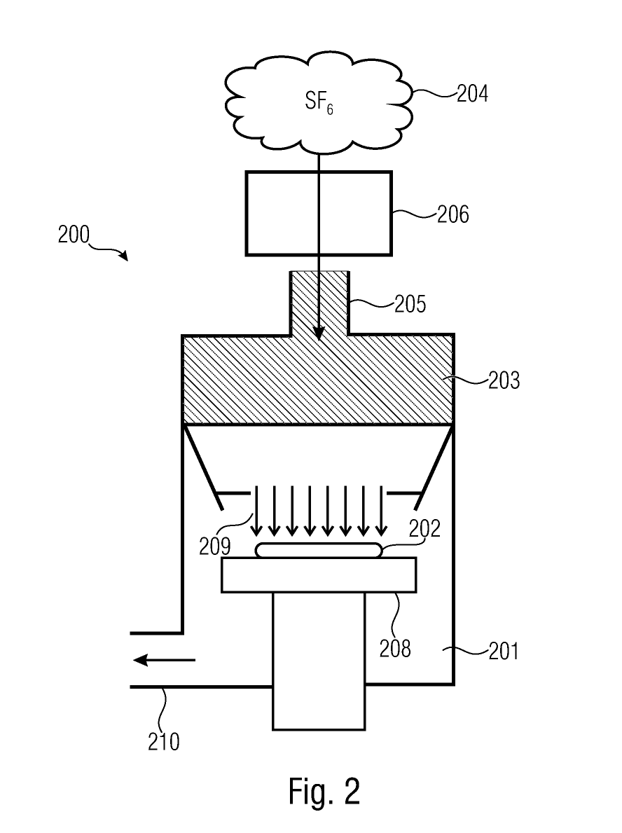

FIG. 2 shows a conventional plasma system 200 for deep reactive-ion etching according to the conventional technology. The plasma system 200 comprises a process chamber 201 containing a substrate 202 to be structured. The plasma system 200 also comprises a chamber with a plasma source 203, into which SF₆ may be introduced as process gas 204 via a gas inlet 205. The process gas 204, here SF₆, is guided to the plasma source 203 via an upstream mass flow controller 206.

Previously used plasma systems, as shown in FIG. 2, would either have to be modified for using inventive fluorine gas mixtures in order to be able to fulfill the higher security requirements, or a new reactor would have to be designed in such a way that the use of fluorine gas mixtures according to the invention is possible without safety concerns, since F₂-gas mixtures are toxic and highly corrosive.

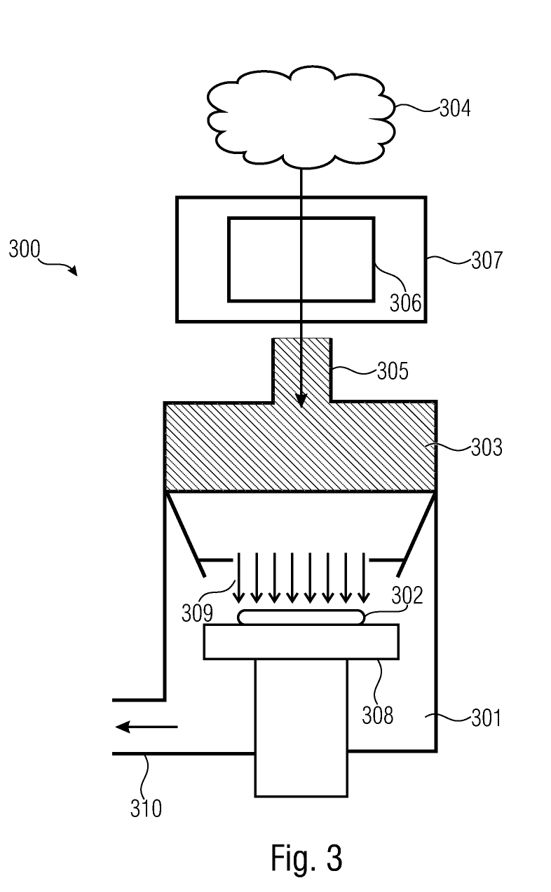

It is therefore proposed, as shown in FIG. 3, to provide a plasma system 300 which has a suction device 307 for a mass flow controller 306 (MFC), wherein the mass flow controller 306 transports the inventive fluorine gas mixture 304 into the process chamber or vacuum chamber 301.

FIG. 3 shows an inventive plasma system 300 for deep reactive-ion etching. The plasma system 300 comprises a process chamber 301 containing a substrate 302 to be structured. Furthermore, the plasma system 300 comprises a chamber having a plasma source 303. Compared to the conventional technology (FIG. 2), the claimed fluorine gas mixture used as the process gas 304 is guided into the inventive plasma system 300 via a gas inlet 305. The fluorine gas mixture is guided to the plasma source 303 via an upstream mass flow controller 306, wherein the previously-mentioned suction device 307 is additionally provided.

The two plasma systems 200, 300 have in common that the substrates 202, 302 to be structured is arranged on an electrode 208, 308 to which the ion or gas flow 209, 309 is directed (high anisotropy). In addition, both plasma systems 200, 300 have a connection 210, 310 for a vacuum pump.

In the following, additional embodiments and aspects of the invention will be described which can be used individually or in combination with any of the features and functionalities and details described herein.

According to an aspect, an etching method comprises: anisotropically structuring a substrate 101, 302 by means of deep reactive-ion etching (DRIE) with several alternating successive etching steps and passivation steps, wherein a fluorine gas mixture is used for etching, comprising a proportion of more than 25% up to and including 40% of fluorine, a proportion of 1% to 50% of nitrogen and a proportion of 30% up to and including 60% of a noble gas.

According to a second aspect when referring back to the first aspect, the fluorine gas mixture comprises a proportion of 35% up to and including 40% of fluorine, a proportion of 1% to 50% of nitrogen and a proportion of 30% up to and including 59% of a noble gas.

According to a third aspect when referring back to the first or second aspect, the fluorine gas mixture comprises a noble gas from the group consisting of argon, neon, krypton, helium, radon and xenon.

According to a fourth aspect when referring back to the first or second aspect, the fluorine gas mixture comprises argon as the noble gas component.

According to a fifth aspect when referring back to the first to fourth aspects, the step of passivating includes applying a passivation layer onto the substrate 101, 302 using SF₄ or C₄F₆ as the process gas.

According to a sixth aspect when referring back to the first to fifth aspects, the method includes generating reactive ions in a high-frequency direct plasma.

According to a seventh aspect when referring back to the sixth aspect, the method includes generating reactive ions in an inductively or capacitively coupled high-frequency direct plasma with an excitation frequency in the shortwave frequency band in a frequency range of 3 MHz to 30 MHz, preferably in a range of 13 MHz to 15 MHz, and particularly preferably in a range of 13.5 MHz to 13.6 MHz.

According to an eighth aspect when referring back to the first to sixth aspects, the method includes generating reactive ions in a high-frequency plasma with an excitation frequency in the microwave frequency band in a frequency range of 0.3 GHz to 3 GHz, preferably in a frequency range of 0.8 GHz to 2.6 GHz, and particularly preferably at a frequency of 2.45 GHz.

According to a ninth aspect when referring back to the first to eighth aspects, the method includes generating reactive ions and radicals, wherein more reactive ions are generated in a first time period than radicals, and wherein more radicals are generated in a subsequent second time period than reactive ions.

A tenth aspect relates to a use of a fluorine gas mixture for anisotropically structuring a substrate 101, 302 by means of deep reactive-ion etching (DRIE) with several alternating successive etching steps and passivation steps, wherein the fluorine gas mixture comprises a proportion of more than 25% up to and including 40% of fluorine, a proportion of 1% up to 50% of nitrogen and a proportion of 30% up to and including 60% of a noble gas from the group consisting of argon, neon, krypton, helium, radon and xenon.

According to an eleventh aspect when referring back to the tenth aspect, the fluorine gas mixture comprises a proportion of 35% up to and including 40% of fluorine, a proportion of 1% to 50% of nitrogen and a proportion of 30% up to and including 59% of a noble gas.

According to a twelfth aspect, an apparatus 300 comprises: a reactor 301 for anisotropically structuring a substrate 302 by means of deep reactive-ion etching (DRIE) with several alternating successive etching steps and passivation steps, and a gas inlet 305 for feeding an etching gas 304 into the reactor 301, a fluorine gas mixture is used as the etching gas 304, comprising a proportion of more than 25% up to and including 40% of fluorine, a proportion of 1% to 50% of nitrogen and a proportion of 30% up to and including 60% of a noble gas.

According to a thirteenth aspect when referring back to the twelfth aspect, the fluorine gas mixture comprises a proportion of 35% up to and including 40% of fluorine, a proportion of 1% to 50% of nitrogen and a proportion of 30% up to and including 59% of a noble gas.

According to a fourteenth aspect when referring back to the twelfth or thirteenth aspect, the fluorine gas mixture 304 at least comprises one noble gas from the group consisting of argon, neon, krypton, helium, radon and xenon.

According to a fifteenth aspect when referring back to the twelfth or thirteenth aspect, the fluorine gas mixture 304 exclusively comprises argon as the noble gas component.

According to a sixteenth aspect when referring back to the twelfth to fifteenth aspect, the apparatus 300 comprises a plasma source 303 configured to generate reactive ions in a high-frequency direct plasma.

According to a seventeenth aspect when referring back to the sixteenth aspect, the plasma source 303 is configured to generate reactive ions in an inductively or capacitively coupled high-frequency direct plasma with an excitation frequency in the shortwave frequency band in a frequency range of 3 MHz to 30 MHz, preferably in a range of 13 MHz to 15 MHz, and particularly preferably in a range of 13.5 MHz to 13.6 MHz.

According to an eighteenth aspect when referring back to the twelfth to sixteenth aspect, the apparatus 300 comprises a plasma source 303 configured to generate reactive ions in a high-frequency plasma with an excitation frequency in the microwave frequency band in a frequency range of 0.3 GHz to 3 GHz, preferably in a frequency range of 0.8 GHz to 2.6 GHz, and particularly preferably at a frequency of 2.45 GHz.

According to a nineteenth aspect when referring back to the sixteenth to eighteenth aspect, the plasma source 303 comprises several individually controllable microwave sources combined in a matrix-like regularly distributed planar arrangement.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. An etching method comprising:
anisotropically structuring a substrate by means of deep reactive-ion etching (DRIE) with several alternating successive etching steps and passivation steps,
wherein a fluorine gas mixture is used for etching, comprising a proportion of more than 25% up to and including 40% of fluorine, a proportion of 1% to 50% of nitrogen and a proportion of 30% up to and including 60% of a noble gas.

2. The etching method according to claim 1, wherein the fluorine gas mixture comprises a proportion of 35% up to and including 40% of fluorine, a proportion of 1% to 50% of nitrogen and a proportion of 30% up to and including 59% of a noble gas.

3. The method according to claim 1, wherein the fluorine gas mixture comprises a noble gas from the group consisting of argon, neon, krypton, helium, radon and xenon.

4. The method according to claim 1, wherein the fluorine gas mixture comprises argon as the noble gas component.

5. The method according to claim 1, wherein passivating comprises applying a passivation layer onto the substrate using SF₄ or C₄F₆ as the process gas.

6. The method according to claim 1, wherein the method comprises generating reactive ions in a high-frequency direct plasma, wherein in the high-frequency direct plasma the plasma is generated directly in an etching chamber with an excitation frequency of 3 MHz to 300 GHz.

7. The method according to claim 6, wherein the method comprises generating reactive ions in an inductively or capacitively coupled high-frequency direct plasma with an excitation frequency in the shortwave frequency band in a frequency range of 3 MHz to 30 MHz, advantageously in a range of 13 MHz to 15 MHz, and particularly advantageously in a range of 13.5 MHz to 13.6 MHz.

8. The method according to claim 1, wherein the method comprises generating reactive ions in a high-frequency plasma with an excitation frequency in the microwave frequency band in a frequency range of 0.3 GHz to 3 GHz, advantageously in a frequency range of 0.8 GHz to 2.6 GHz, and particularly advantageously at a frequency of 2.45 GHz.

9. The method according to claim 1, wherein the method comprises generating reactive ions and radicals, wherein more reactive ions are generated in a first time period than radicals, and wherein more radicals are generated in a subsequent second time period than reactive ions.

10. The method according to claim 1, wherein the substrate is at least one of a semiconductor substrate or a silicon substrate.

11. A use of a fluorine gas mixture for anisotropically structuring a silicon substrate by means of deep reactive-ion etching (DRIE) with several alternating successive etching steps and passivation steps, wherein the fluorine gas mixture is used for etching and comprises a proportion of more than 25% up to and including 40% of fluorine, a proportion of 1% up to 50% of nitrogen and a proportion of 30% up to and including 60% of a noble gas from the group comprising argon, neon, krypton, helium, radon and xenon.

12. The use of a fluorine gas mixture according to claim 11, wherein the fluorine gas mixture comprises a proportion of 35% up to and including 40% of fluorine, a proportion of 1% to 50% of nitrogen and a proportion of 30% up to and including 59% of a noble gas.

13. An apparatus comprising:
a reactor for anisotropically structuring a substrate by means of deep reactive-ion etching (DRIE) with several alternating successive etching steps and passivation steps,
and a gas inlet for feeding an etching gas into the reactor, wherein a fluorine gas mixture is used as the etching gas, comprising a proportion of more than 25% up to and including 40% of fluorine, a proportion of 1% to 50% of nitrogen and a proportion of 30% up to and including 60% of a noble gas.

14. The apparatus according to claim 13, wherein the fluorine gas mixture comprises a proportion of 35% up to and including 40% of fluorine, a proportion of 1% to 50% of nitrogen and a proportion of 30% up to and including 59% of a noble gas.

15. The apparatus according to claim 13, wherein the fluorine gas mixture at least comprises one noble gas from the group consisting of argon, neon, krypton, helium, radon and xenon.

16. The apparatus according to claim 13, wherein the fluorine gas mixture exclusively comprises argon as the noble gas component.

17. The apparatus according to claim 13, wherein the apparatus comprises a plasma source configured to generate reactive ions in a high-frequency direct plasma.

18. The apparatus according to claim 17, wherein the plasma source is configured to generate reactive ions in an inductively or capacitively coupled high-frequency direct plasma with an excitation frequency in the shortwave frequency band in a frequency range of 3 MHz to 30 MHz, preferably in a range of 13 MHz to 15 MHz, and particularly preferably in a range of 13.5 MHz to 13.6 MHz.

19. The apparatus according to claim 13, wherein the apparatus comprises a plasma source configured to generate reactive ions in a high-frequency plasma with an excitation frequency in the microwave frequency band in a frequency range of 0.3 GHz to 3 GHz, preferably in a frequency range of 0.8 GHz to 2.6 GHz, and particularly preferably at a frequency of 2.45 GHz.

20. The apparatus according to claim 19, wherein the plasma source comprises several individually controllable microwave sources combined in a matrix-like regularly distributed planar arrangement.
